(19) United States
(12) Patent Application Publication
(10) Pub. No.: US 2009/0052242 A1
(43) Pub. Date: Feb. 26, 2009

(54) NAND TYPE NONVOLATILE SEMICONDUCTOR MEMORY

(76) Inventors: Hideto Takekida, Yokohama-shi (JP); Atsuhiro Sato, Yokohama-shi (JP); Fumitaka Arai, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/194,655

(22) Filed: Aug. 20, 2008

(30) Foreign Application Priority Data
Aug. 20, 2007 (JP) 2007-213878

(51) Int. Cl. G11C 16/04; G11C 16/06

(52) U.S. Cl. 365/185.03; 365/185.18

(57) ABSTRACT

A memory includes n-numbered memory cells (n is an integer of not less than 3) and a driver which applies a first voltage to a control gate electrode of a selected first memory cell in the n-numbered memory cells, applies a second voltage lower than the first voltage to a control gate electrode of a second memory cell adjacent to the first memory cell, and applies a third voltage lower than the second voltage to control gate electrodes of third memory cells other than the first and second memory cells at the time of programming. The first, second and third voltages have values not less than a value for turning on the n-numbered memory cells regardless of their threshold voltages.

### CROSS-REFERENCE TO RELATED APPLICATIONS

This application is based upon and claims the benefit of priority from prior Japanese Patent Application No. 2007-213878, filed Aug. 20, 2007, the entire contents of which are incorporated herein by reference.

### BACKGROUND OF THE INVENTION

1. Field of the Invention

The present invention relates to a programming system of a NAND type nonvolatile semiconductor memory.

2. Description of the Related Art

In recent years, application using NAND type nonvolatile semiconductor memories are being widened, and their memory capacities are increasing. However, when memory cells are miniaturized due to the increase in the memory capacities, a problem of writing disturb arises.

For example, the programming system of the NAND type nonvolatile semiconductor memories includes a self-boost (SB) system (for example, see K. D. Suh et. al., IEEE Journal of Solid-State Circuits, vol. 30, No. 11 (1995) pp. 1149 to 1156) and a local self-boost (LSB) system (for example, see Jpn. Pat. Appln. KOKAI Publication No. 8-279297).

In programming using these systems, leak current flow between a control gate electrode of the selected cells and a floating gate electrode of the adjacent cells, when programming is finished in adjacent cells (non-selected cells) adjacent to source sides of selected cells to be programmed. As a result, threshold voltage of the adjacent cell shifts.

This problem becomes noticeable as the memory cells are further miniaturized and gaps between memory cells connected in series in a NAND cell unit become narrower.

The programming system includes two kinds of systems: a random program and a sequential program. In the latter one, programming is successively executed one by one from a memory cell closest to a source line towards a memory cell closest to a bit line in the memory cells of the NAND cell unit.

For this reason, the problem of the shift of the threshold voltage always arises in the sequential program.

Recently, as a technique which contributes to the increase in the memory capacity, an attention has been paid to a multi-level technology for storing not less than three-valued data in one memory cell.

In the NAND type nonvolatile semiconductor memories to which this multi-level technology is applied, three or more threshold voltage distributions should be set within a narrow voltage range. As a result, a margin between the threshold voltage distributions is very narrow, and thus the problem of the threshold fluctuation becomes more serious.

### BRIEF SUMMARY OF THE INVENTION

A NAND type nonvolatile semiconductor memory according to an aspect of the present invention comprises n-numbered memory cells (n is an integer of not less than 3) which have a charge storage layer and a control gate electrode and are connected to each other in series, first select gate transistors which are connected between one ends of the n-numbered memory cells and source lines, second select gate transistors which are connected between the other ends of the n-numbered memory cells and bit lines, and a driver which applies a first voltage to a control gate electrode of a selected first memory cell in the n-numbered memory cells, applies a second voltage lower than the first voltage to a control gate electrode of a second memory cell adjacent to the first memory cell, and applies a third voltage lower than the second voltage to control gate electrodes of third memory cells other than the first and second memory cells at the time of programming. The first, second and third voltages have values not less than a value for turning on the n-numbered memory cells regardless of their threshold voltages.

### BRIEF DESCRIPTION OF THE SEVERAL VIEWS OF THE DRAWING

FIG. 1 is a block diagram showing a NAND type nonvolatile semiconductor memory;

FIG. 2 is a diagram showing a circuit example of a memory cell array and a word line driver;

FIG. 3 is a plan view showing a NAND cell unit;

FIG. 4 is a cross-sectional view showing a NAND cell unit;

FIG. 5 is a diagram showing a programming system according to a first example;

FIG. 6 is a diagram showing a programming system according to a second example;

FIG. 7 is a diagram showing a programming system according to a third example;

FIG. 8 is a diagram showing a programming system according to a fourth example;

FIG. 9 is a diagram showing a relationship between a transfer voltage and a shift of a threshold voltage;

FIG. 10 is a diagram showing a self-boost system;

FIG. 11 is a diagram showing a local self-boost system;

FIG. 12 is a diagram showing optimization of the transfer voltage;

FIG. 13 is a diagram showing a MONOS memory cell;

FIG. 14 is a diagram showing a system as an applied example;

FIG. 15 is a diagram showing a chip layout as an applied example; and

FIG. 16 is a diagram showing the NAND cell unit.

### DETAILED DESCRIPTION OF THE INVENTION

A NAND type nonvolatile semiconductor memory of an aspect of the present invention will be described below in detail with reference to the accompanying drawings.

### 1. OUTLINE

In a NAND type nonvolatile semiconductor memory, a program voltage Vpgm is applied to a control gate electrode of selected cells at the time of programming, and a transfer voltage Vpass which is lower than the program voltage Vpgm is applied to control gate electrodes of non-selected cells.

In an example of the present invention, at least two transfer voltages Vpass are prepared.

One of them is a transfer voltage Vpash which is applied to a control gate electrode of adjacent cells (non-selected cells) adjacent to the selected cells. The other one is transfer voltage Vpass which is lower than transfer voltage Vpash applied to the control gate electrodes of the selected cells and the non-selected cells other than the adjacent cells.

That is, Vpass<Vpash<Vpgm.

The three voltages Vpass, Vpash and Vpgm have values not less than a value for turning on the memory cells in a NAND string regardless of threshold voltage.

In this case, a voltage of a charge storage layer (for example, a floating gate electrode) of the adjacent cell becomes higher than that when transfer voltage Vpass is applied to the control gate electrode of the adjacent cells. For this reason, an electric field between the control gate electrode of the selected cells and the floating gate electrode of the adjacent cells is alleviated.

Therefore, the shift of the threshold voltage of the adjacent cell due to a leak current is prevented.

For example, when the adjacent cells are in a writing state, namely, electrons have been injected into the charge storage layer, the electrons are not taken out from the charge storage layer by the control gate electrode of the selected cells, and thus erase error (decrease in the threshold voltage) is prevented.

In the non-selected cells other than the adjacent cell, since transfer voltage Vpass is applied to the control gate electrode, write error (increase in the threshold voltage) due to a tunnel current is not produced.

In the example of the present invention, an effect is produced within a range of Vpass<Vpash<Vpgm, but the value of transfer voltage Vpash is set to an optimum value within the above range in order to prevent both the shift of the threshold voltage due to leak and the write error due to the tunnel current.

### 2. EXAMPLES

### (1) NAND Type Nonvolatile Semiconductor Memory

An outline of the NAND type nonvolatile semiconductor memory will be described.

In the following description, binary is premised for convenience.

A state that the threshold voltage of the memory cell is low is an erase state (1-state), and a state that it is high is a write state (0-state). An initial state of the memory cells is the erase state.

The programming includes 1-programming and 0-programming; the former one means inhibition of writing (erase state is maintained), and the latter one means execution of writing (increase in threshold voltage).

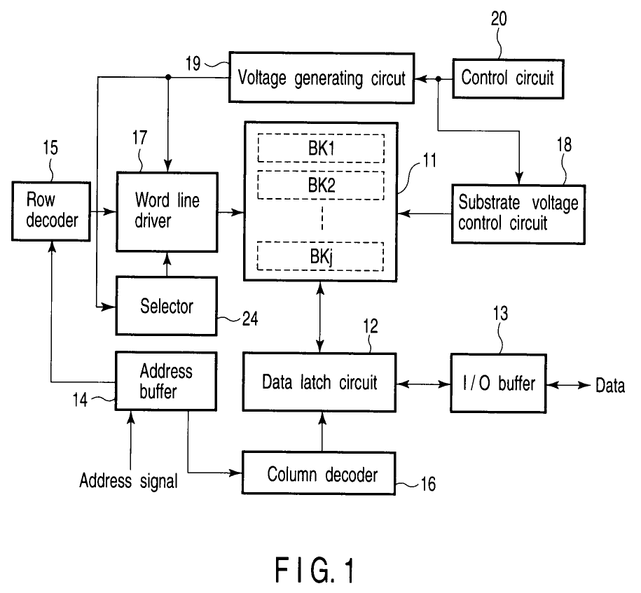

FIG. 1 is an overall view showing the NAND type nonvolatile semiconductor memory.

A memory cell array 11 has blocks BK1, BK2, BLj. Each of the blocks BK1, BK2, . . . , BLj has a NAND cell unit.

A data latch circuit 12 has a function for temporarily latching data at the time of reading/programming, and is composed of a flip-flop circuit, for example. An I/O (input/output) buffer 13 functions as an interface circuit for data, and an address buffer 14 functions as an interface circuit for an address signal.

The address signal includes a block address signal, a row address signal and a column address signal.

A row decoder 15 selects one of the blocks BK1, BK2, . . . , BLj based on a block address signal, and selects one of word lines in the selected block based on a row address signal. A word line driver 17 drives the word lines in the selected block.

A column decoder 16 selects one of bit lines based on a column address signal.

A substrate voltage control circuit 18 controls a voltage of a semiconductor substrate. Specifically, a double well region composed of an n-type well region and a p-type well region is formed in a p-type semiconductor substrate. When the memory cell is formed in the p-type well region, a voltage of the p-type well region is controlled according to an operation mode.

For example, the substrate voltage control circuit 18 sets the voltage of the p-type well region to 0V at the time of reading/programming, and sets the voltage of the p-type well region to 15V or more to 40V or less at the time of erase.

A voltage generating circuit 19 generates a voltage for controlling the word line driver 17.

In the present invention, the voltage generating circuit 19 generates voltages to be supplied to the word lines in the selected blocks, namely, a program voltage Vpgm and two transfer voltages Vpash and Vpass.

A selector 24 selects values of the voltages to be supplied to the word lines in the selected block based on information about the operation mode and a position of the selected word line.

A control circuit 20 controls operations of the substrate voltage control circuit 18 and the voltage generating circuit 19.

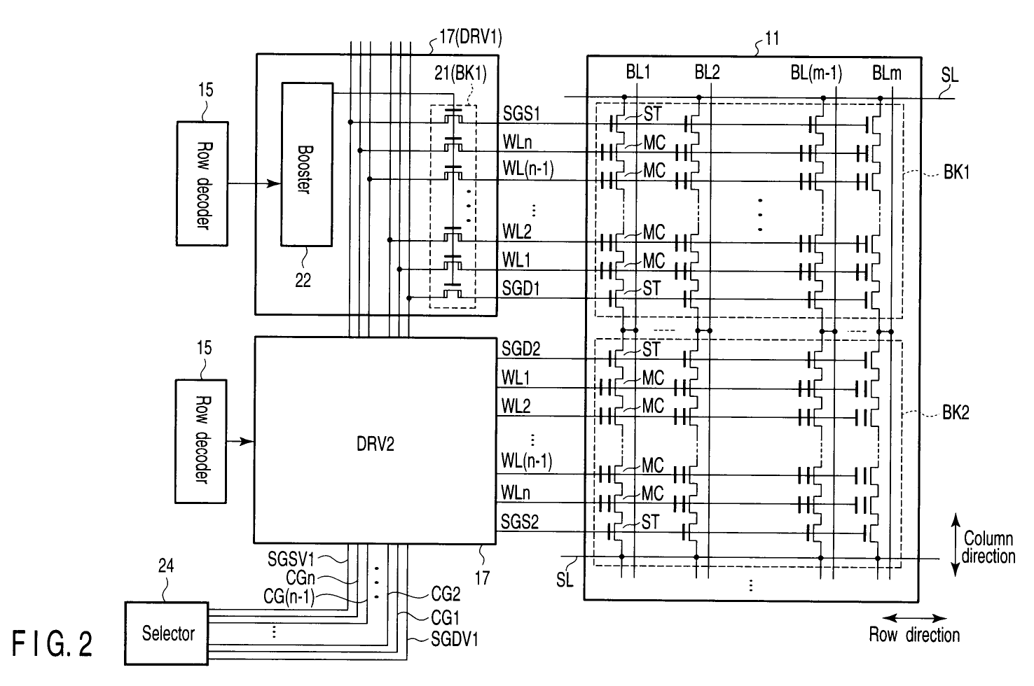

FIG. 2 illustrates a circuit example of the memory cell array and the word line driver.

The memory cell array 11 has the blocks BK1, BK2, . . . which are arranged in a column direction. Each of the blocks BK1, BK2, . . . has NAND cell units which are arranged in a row direction. The NAND cell unit has a NAND string composed of memory cells MC connected in series, and two select gate transistors ST connected to both ends of the NAND string, respectively.

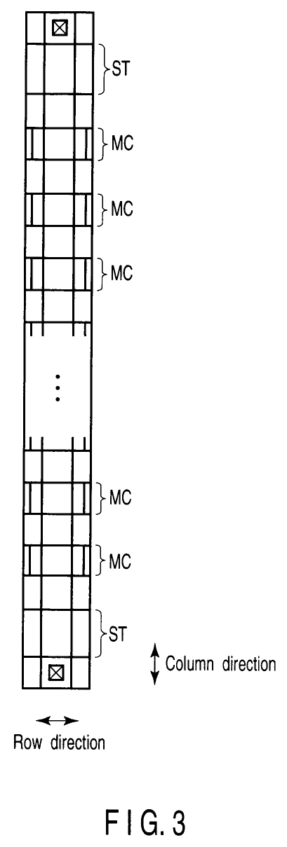

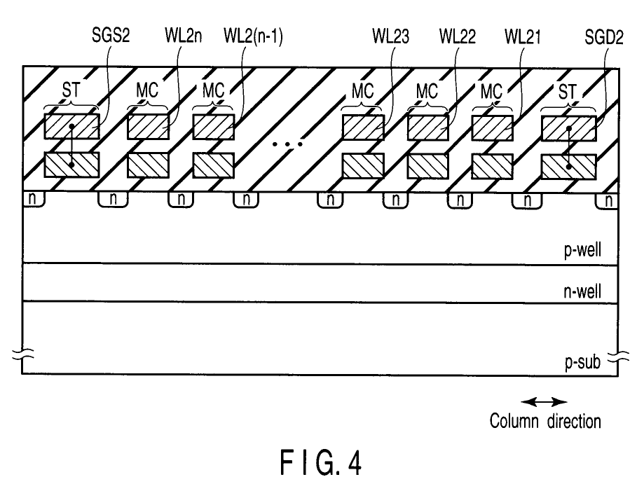

The NAND cell unit has a layout shown in FIG. 3, for example. A sectional structure of the NAND cell unit in the column direction is as shown in FIG. 4, for example.

One end of the NAND cell unit is connected to the bit lines BL1, BL2, . . . , BLm, and the other end is connected to a source line SL.

Word lines WL1, . . . , WLn, . . . , and select gate lines SGS1, SGD1, . . . are arranged on the memory cell array 11.

The n-numbered (n is plural) word lines WL1, WLn and the two select gate lines SGS1 and SGD1 are arranged in the block BK1. The word lines WL1, WLn and the select gate lines SGS1 and SGD1 extend in the row direction, and they are connected to signal lines (control gate lines) CG1, . . . , CGn and signal lines SGSV1 and SGDV1 via a transfer transistor unit 21 (BK1) in the word line driver 17 (DRV1).

The signal lines CG1, . . . , CGn, SGSV1 and SGDV1 extend in the column direction which crosses the row direction and are connected to a selector 24.

The transfer transistor unit 21 (BK1) is composed of a high-voltage MISFET so as to be capable of transferring a voltage higher than a power supply voltage Vcc.

A booster 22 in the word line driver 17 (DRV1) receives a decode signal output from the row decoder 15. When the block BK1 is selected, the booster 22 turns on the transfer transistor unit 21 (BK1), and when the block BK1 is not selected, it turns off the transfer transistor unit 21 (BK1).

### (2) Programming Operation

### A. First Example

In a first example, Vpash is supplied to a control gate electrode of adjacent cells adjacent to source line sides of selected cells.

In the first example, both a random program and a sequential program are used, but since the adjacent cells are adjacent to the source line sides of the selected cells, the first example is particularly effective for the sequential program.

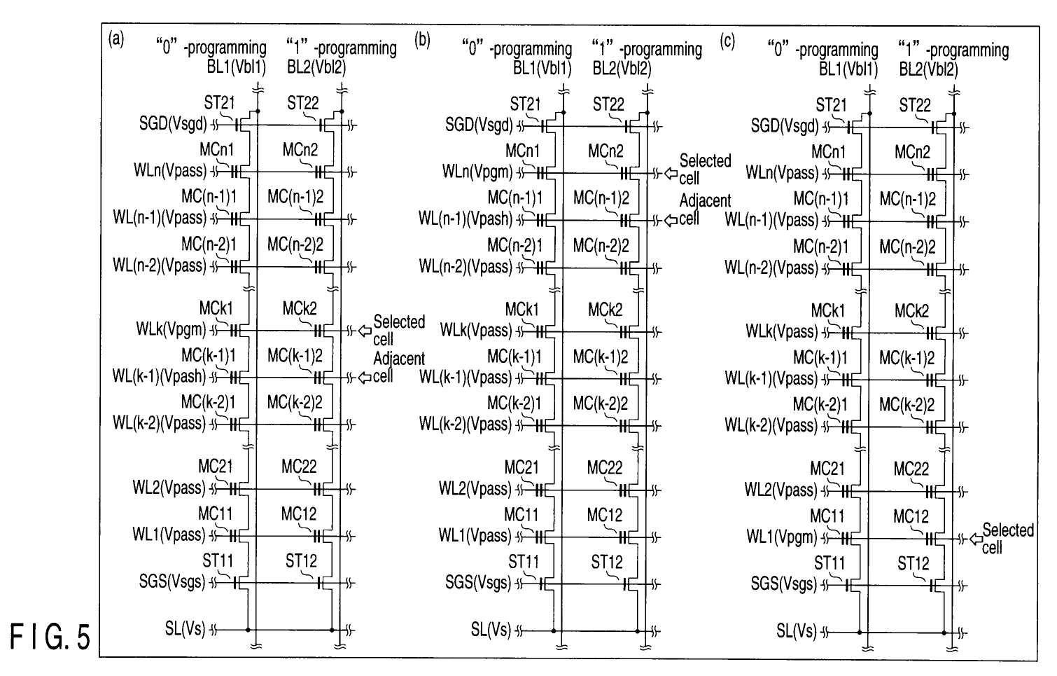

FIG. 5 illustrates a voltage relationship in the NAND cell unit at the time of programming.

A case where central memory cells MCk1 and MCk2 in the NAND string are selected cells will be described with reference to (a) of FIG. 5.

A program voltage Vpgm is applied to the word line WLk.

A transfer voltage Vpash is applied to a control gate electrode of adjacent cells MC(k−1)1 and MC(k−1)2 adjacent to the source line SL sides of selected cells MCk1 and MCk2, namely, a word line WL(k−1).

A transfer voltage Vpass is applied to other word lines WL1, . . . , WL(k−2), WL(k+1), . . . , WLn.

A relationship among these three voltages is Vpass<Vpash<Vpgm.

Vpass, Vpash and Vpgm have values not less than a value for turning on the memory cells in the NAND string regardless of their threshold voltages.

It is considered that binary 0 is programmed in the selected cell MCk1, and binary 1 is programmed in the selected cell MCk2.

Initial states of the selected cells MCk1 and MCk2 are in the erase state (1-state).

In this case, the bit line BL1 is set at a low voltage Vbl1 (for example, 0V) for the 0-programming, and the bit line BL2 is set at a positive voltage Vbl2 (for example, 1.2 to 4.0V) for the 1-programming.

A voltage Vsgd is applied to the bit line side select gate line SGD. The value of Vsgd satisfies the following relationship:

Vth_{—}sgd(0)<Vsgd<Vbl2+Vth_{—}sgd(Vbl2).

Vth_sgd means threshold voltages of bit line side select gate transistors ST21 and ST22, and symbols in parentheses mean back bias voltages to be applied to sources of the bit line side select gate transistors ST21 and ST22.

Normally, Vsgd is set to the same value as Vbl2.

A voltage Vsgs (for example, 0V) for cutting off the source line side select gate transistors ST11 and ST12 is applied to the source line side select gate line SGS.

The source line SL is set to Vs, for example, 0V.

As a result, the select gate transistor ST21 is turned on, and the voltage Vbl1 is transferred from the bit line BL1 to a channel of the selected cell MCk in the NAND string.

Therefore, when Vpgm is applied to the word line WLk, electrons are injected into a charge storage layer (for example, floating gate electrode) from the channel in the selected cell MCk1, so that writing is carried out (threshold voltage rises).

On the other hand, when the voltages Vpash and Vpass are applied to the word lines, the channels of the memory cells in the NAND string are boosted due to a capacity coupling. For this reason, the select gate transistor ST22 is automatically cut off.

When the voltage Vpgm is applied to the word line WLk, the channel voltage of the selected cell MCk2 further rises. In the selected cell MCk2, therefore, electrons are not injected from the channel into the charge storage layer, and writing is inhibited (erase state is maintained).

In such a programming operation, transfer voltage Vpash higher than transfer voltage Vpass is applied to the control gate electrode of the adjacent cells MC(k−1)1 and MC(k−1)2, namely, the word line WL(k−1).

For this reason, even if programming is already finished in the adjacent cells (non-selected cells) MC(k−1)1 and MC(k−1)2 at the time of programming, a shift of threshold voltages of the adjacent cells due to leak between the control gate electrode of the selected cells and the charge storage layer of the adjacent cells can be prevented.

A case where the memory cells MCn1 and MCn2 which are the closest to the bit line side in the NAND string are the selected cells will be described with reference to (b) of FIG. 5.

A program voltage Vpgm is applied to the word line WLn.

A transfer voltage Vpash is applied to the control gate electrode of the adjacent cells MC(n−1)1 and MC(n−1)2 adjacent to the source line SL sides of the selected cells MCn1 and MCn2, namely, the word line WL(n−1).

A transfer voltage Vpass is applied to the other word lines WL1, . . . and WL(n−2).

When binary 0 is programmed in the selected cell MCn1 and binary 1 is programmed in the selected cell MCn2, the bit line BL is set to Vbl1, and the bit line BL2 is set to Vbl2 similarly to above.

Initial states of the selected cells MCn1 and MCn2 are in the erase state (1-state).

A voltage Vsgd is applied to the bit line side select gate line SGD. A voltage Vsgs for cutting off the source line side select gate transistors ST11 and ST12 is applied to the source line side select gate line SGS.

The source line SL is set to Vs, for example, 0V.

As a result, the select gate transistor ST21 is turned on, and the voltage Vbl1 is transferred from the bit line BL1 to the channel of the selected cell MCn1 in the NAND string.

Therefore, when the program voltage Vpgm is applied to the word line WLn, electrons are injected into the charge storage layer (for example, floating gate electrode) from the channel in the selected cell MCn1, so that writing is carried out (threshold voltage rises).

On the other hand, when transfer voltages Vpash and Vpass are applied to the word lines, the channels of the memory cells in the NAND string are boosted due to capacity coupling. For this reason, the select gate transistor ST22 is automatically cut off.

When the program voltage Vpgm is applied to the word line WLn, the channel voltage of the selected cell MCn2 further rises. Therefore, electrons are not injected into the charge storage layer from the channel in the selected cell MCn2, so that writing is inhibited (erase state is maintained).

In such a programming operation, transfer voltage Vpash which is higher than transfer voltage Vpass is applied to the control gate electrode of the adjacent cells MC(n−1)1 and MC(n−1)2, namely, the word line WL(n−1).

For this reason, even if programming is already finished in the adjacent cells (non-selected cells) MC(n−1)1 and MC(n−1)2 at the time of programming, a shift of the threshold voltages of the adjacent cells due to the leak between the control gate electrode of the selected cells and the charge storage layer of the adjacent cells can be prevented.

A case where the memory cells MC11 and MC12 which are the closest to the source line side in the NAND string are the selected cells will be described with reference to (c) of FIG. 5.

In this case, since no cells adjacent to the source line SL sides of the selected cells MC11 and MC12 are present, the program voltage Vpgm is applied to the word line WL1, and transfer voltage Vpass is applied to all the other word lines WL2, . . . , WLn.

Programming is carried out similarly to FIG. 5.

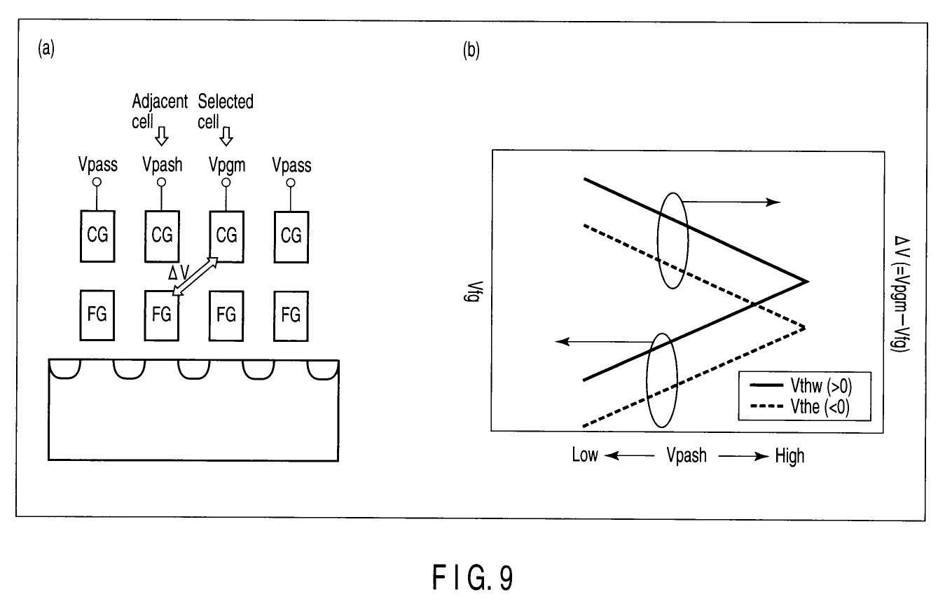

FIG. 9 illustrates a relationship between a voltage ΔV between the control gate electrode of the selected cells and the charge storage layer of the adjacent cells, and transfer voltage Vpash.

The value of ΔV accords with the amount of leak produced between the control gate electrode of the selected cells and the charge storage layer of the adjacent cells.

Vfg represents a voltage of the floating gate electrodes of the adjacent cells, and is expressed by:

Vfg=Cpr(Vg−Vth)

Cpr=Cono/(Cono+Cox).

Vg represents the voltage Vpash of the control gate electrode of the adjacent cells, Vth represents the threshold voltages of the adjacent cells, and Cpr represents a coupling ratio.

Cono represents capacities of inter-gate insulating films of the adjacent cells, and Cox represents capacities of tunnel insulating films (gate insulating films) of the adjacent cells. The inter-gate insulting film is an insulating film between the floating gate electrode and the control gate electrode.

The threshold voltage Vth of the adjacent cell includes Vthw (>0) in the writing state and Vthe (<0) in the erase state.

As is clear from FIG. 9, the floating gate electrode voltage Vfg increases according to an increase in transfer voltage Vpash, and ΔV(=Vpgm−Vfg) decreases.

As to the threshold voltages Vthe and Vthw of the adjacent cells, ΔV in the writing state (Vthw) is higher than ΔV in the erase state (Vthe).

This means that when the adjacent cells are in the writing state, the shift of the threshold voltages of the adjacent cells (erase error) particularly becomes problem.

According to the first example, when transfer voltage Vpash is increased, the value ΔV can be reduced. For this reason, the shift of the threshold voltage at the time when the adjacent cells are in the writing state can be effectively prevented.

### B. Second Example

In the second example, the adjacent cells are adjacent to the source line sides of the selected cells similarly to the first example.

Characteristic of the second example is that a local self-boost system is combined with the first example.

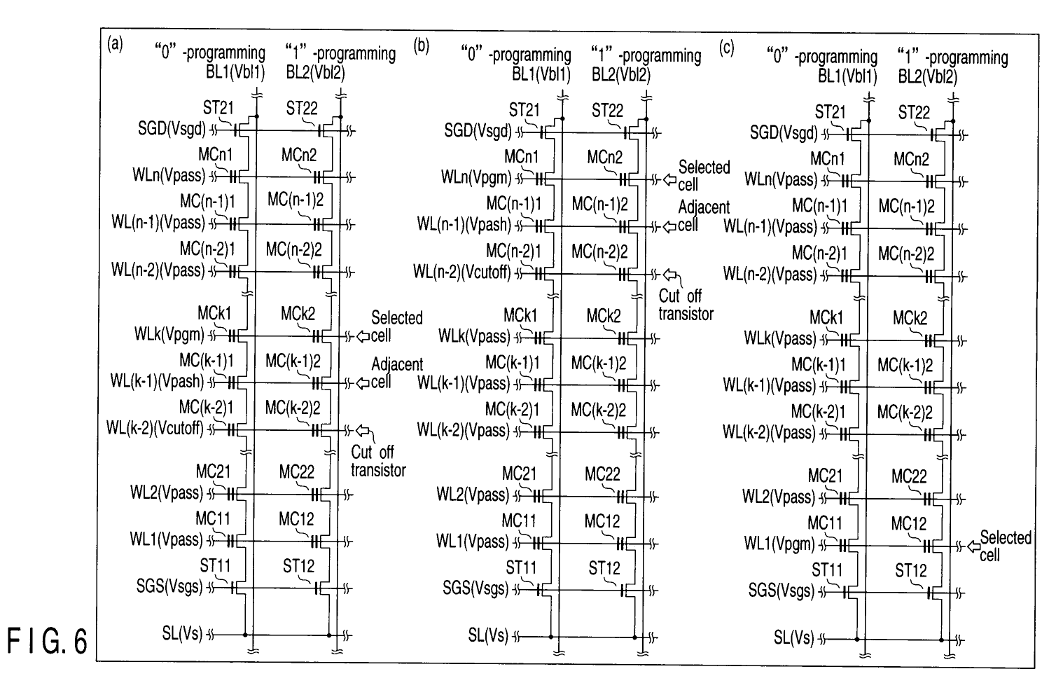

FIG. 6 illustrates a voltage relationship in the NAND cell unit at the time of programming.

A case where the central memory cells MCk1 and MCk2 in the NAND string are the selected cells will be described with reference to (a) of FIG. 6.

A program voltage Vpgm is applied to the word line WLk.

A transfer voltage Vpash is applied to the control gate electrode of the adjacent cells MC(k−1)1 and MC(k−1)2 adjacent to the source line SL sides of the selected cells MCk1 and MCk2, namely, the word line WL(k−1).

A cut off voltage Vcutoff (for example, 0V) for cutting off non-selected cells MC(k−2)1 and MC(k−2)2 is applied to the control gate electrode of the non-selected cells MC(k−2)1 and MC(k−2)2 adjacent to the source line SL sides of the adjacent cells MC(k−1)1 and MC(k−1)2, namely, the word line WL(k−2).

A transfer voltage Vpass is applied to the other word lines WL1, . . . , WL(k−3), WL(k+1), . . . , WLn.

These four voltages hold a relationship of Vcutoff<Vpass<Vpash<Vpgm.

Vpass, Vpash and Vpgm have values not less than a value for turning on the memory cells in the NAND string regardless of their threshold voltages.

It is considered that binary 0 is programmed in the selected cell MCk1 and binary 1 is programmed in the selected cell MCk2.

The initial states of the selected cells MCk1 and MCk2 are the erase state (1-state).

In this case, the bit line BL1 is set at a low voltage Vbl1 (for example, 0V) for the 0-programming, and the bit line BL2 is set at a positive voltage Vbl2 (for example, 1.2 to 4.0V) for the 1-programming.

A voltage Vsgd is applied to the bit line side select gate line SGD. The value Vsgd complies with the condition in the first example.

A voltage Vsgs (for example, 0V) for cutting off the source line side select gate transistors ST11 and ST12 is applied to the source line side select gate line SGS.

The source line SL is set to Vs, for example, 0V.

As a result, the select gate transistor ST21 is turned on, and the voltage Vbl1 is transferred from the bit line BL1 to the channel of the selected cell MCk1 in the NAND string.

Therefore, when the program voltage Vpgm is applied to the word line WLk, electrons are injected into the charge storage layer (for example, floating gate electrode) from the channel in the selected cell MCk1, so that writing is carried out (threshold voltage rises).

On the other hand, when transfer voltages Vpash and Vpass are applied to the word lines, the channels of the memory cells in the NAND string are boosted due to the capacity coupling. For this reason, the select gate transistor ST22 is automatically cut off.

When the program voltage Vpgm is applied to the word line WLk, the channel voltage of the selected cell MCk2 further rises. In the selected cell MCk2, therefore, electrons are not injected from the channel into the charge storage layer, so that writing is inhibited (the erase state is maintained).

As to the inhibition of writing, since the non-selected cells MC(k−2)1 and MC(k−2)2 are in the cut off state due to the cut off voltage Vcutoff, the boost efficiency of the channels of the selected cells is improved.

That is, when not the non-selected cells (cut off transistors) MC(k−2) but only the channels of the bit line side memory cells MC(k−1), . . . , MCn are boosted, the boost ratio is further improved in comparison with the case where the channels of all the memory cells in the NAND string are boosted.

In such a programming operation to which the local self-boost system is applied, transfer voltage Vpash higher than transfer voltage Vpass is applied to the control gate electrode of the adjacent cells MC(k−1)1 and MC(k−1)2, namely, the word line WL(k−1).

For this reason, even if the programming is already finished in the adjacent cells (non-selected cells) MC(k−1)1 and MC(k−1)2 at the time of programming, a shift of the threshold voltages of the adjacent cells due to the leak between the control gate electrode of the selected cells and the charge storage layer of the adjacent cells can be prevented.

An occasion where the memory cells MCn1 and MCn2 which are the closest to the bit line side in the NAND string are selected cells will be described below with reference to (b) of FIG. 6.

A program voltage Vpgm is applied to the word line WLn.

A transfer voltage Vpash is applied to the control gate electrode of the adjacent cells MC(n−1)1 and MC(n−1)2 adjacent to the source line SL sides of the selected cells MCn1 and MCn2, namely, the word line WL(n−1).

A cut off voltage Vcutoff for cutting off the non-selected cells MC(n−2)1 and MC(n−2)2 is applied to the control gate electrode of the non-selected cells MC(n−2)1 and MC(n−2)2 adjacent to the source line SL sides of the adjacent cells MC(n−1)1 and MC(n−1)2, namely, the word line WL(n−2).

A transfer voltage Vpass is applied to the other word lines WL1, . . . , WL(n−2).

When binary 0 is programmed in the selected cell MCn1 and binary 1 is programmed in the selected cell MCn2, the bit line BL1 is set to Vbl1, and the bit line BL2 is set to Vbl2.

The initial states of the selected cells MCn1 and MCn2 are in the erase state (1-state).

A voltage Vsgd is applied to the bit line side select gate line SGD. A voltage Vsgs for cutting off the source line side select gate transistors ST11 and ST12 is applied to the source line side select gate line SGS.

The source line SL is set to Vs, for example, 0V.

As a result, the select gate transistor ST21 is turned on, and the voltage Vbl1 is transferred from the bit line BL1 to the channel of the selected cell MCn1 in the NAND string.

Therefore, when the program voltage Vpgm is applied to the word line WLn, electrons are charged into the charge storage layer (for example, floating gate electrode) from the channel in the selected cell MCn1, so that writing is carried out (threshold voltage rises).

On the other hand, when transfer voltages Vpash and Vpass are applied to the word lines, the channels of the memory cells in the NAND string are boosted due to the capacity coupling. For this reason, the select gate transistor ST22 is automatically cut off.

When the program voltage Vpgm is applied to the word line WLn, the channel voltage of the selected cell MC2 further rises. In the selected cell MCn2, therefore, electrons are not injected into the charge storage layer from the channel, so that writing is inhibited (erase state is maintained).

As to the inhibition of the writing, since the non-selected cells MC(n−2)1 and MC(n−2)2 are in the cut off state due to the cut off voltage Vcutoff, only the channels of the selected cells MCn1 and MCn2 and the adjacent cells MC(n−1)1 and MC(n−1)2 may be boosted. As a result, the boost efficiency of the channels of the selected cells is improved.

In such a programming operation to which the local self-boost system is applied, transfer voltage Vpash higher than transfer voltage Vpass is applied to the control gate electrode of the adjacent cells MC(n−1)1 and MC(n−1)2, namely, the word line WL(n−1).

For this reason, even if programming is already finished in the adjacent cells (non-selected cells) MC(n−1)1 and MC(n−1)2 at the time of programming, the shift of the threshold voltages of the adjacent cells due to the leak between the control gate electrode of the selected cells and the charge storage layer of the adjacent cells can be prevented.

A case where the memory cells MC11 and MC12 which are the closest to the source line side in the NAND string are the selected cells will be described below with reference to (c) of FIG. 6.

In this case, since no adjacent cells adjacent to the source line SL sides of the selected cells MC11 and MC12 are present, the program voltage Vpgm is applied to the word line WL1, and transfer voltage Vpass is applied to all the other word lines WL2, . . . , WLn.

Programming is carried out similarly to FIG. 6.

Also in the second example, since the relationship between ΔV and Vpash holds as shown in FIG. 9, the shift of the threshold voltages can be effectively prevented when the adjacent cells are in the writing state.

In the second example, only one cut off transistor for local self-boost is present, but two or more cut off transistors may be present.

### C. Third Example

In a third example, similarly to the first example, adjacent cells are adjacent to the source line sides of selected cells.

The third example is a modified example of the first example, and its characteristic is that values of transfer voltage Vpass to be supplied to non-selected cells (except for the adjacent cells) vary.

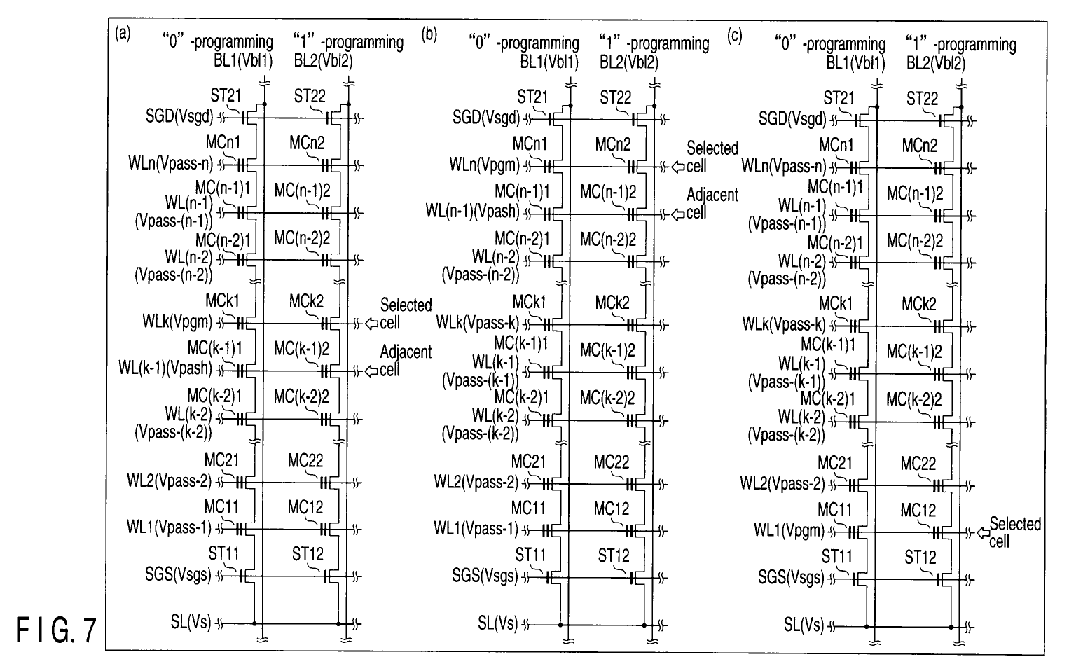

FIG. 7 illustrates a voltage relationship in the NAND cell unit at the time of programming.

A case where the central memory cells MCk1 and MCk2 in the NAND string are the selected cells will be described with reference to (a) of FIG. 7.

A program voltage Vpgm is applied to the word line WLk.

A transfer voltage Vpash is applied to the control gate electrode of the adjacent cells MC(k−1)1 and MC(k−1)2 adjacent to the source line SL side of the selected cells MCk1 and MCk2, namely, the word line WL(k−1).

Transfer voltages Vpass-1, . . . , Vpass-(k−2), Vpass-(k+1), . . . , Vpass-n are applied to the other word lines WL1, . . . , WL(k−2), WL(k+1), . . . , WLn, respectively.

A relationship among these voltages is Vpass-1, . . . , Vpass-(k−2), Vpass-(k+1), . . . , Vpass-n<Vpash<Vpgm.

At least one of Vpass-1, . . . , Vpass-(k−2), Vpass-(k+1), . . . , Vpass-n may be different from the other ones.

That is, only minimum-numbered kinds (not less than two kinds) of transfer voltages Vpass (except for Vpash) are prepared based on position dependence of the memory cells in the NAND string on a voltage stress at the time of supplying the program voltage Vpgm.

As a matter of course, all the values of Vpass-1, . . . , Vpass-(k−2), Vpass-(k+1), . . . , Vpass-n may be varied.

It is considered that binary 0 is programmed in the selected cell MCk1, and binary 1 is programmed in the selected cell MCk2.

Initial states of the selected cells MCk1 and MCk2 are in the erase state (1-state).

In this case, the bit line BL1 is set to a low voltage Vbl1 (for example, 0V) for the 0-programming, and the bit line BL2 is set to a positive voltage Vbl2 (for example, 1.2 to 4.0V) for the 1-programming.

A voltage Vsgd is applied to the bit line side select gate line SGD.

A voltage Vsgs for cutting off the source line side select gate transistors ST11 and ST12 is applied to the source line side select gate line SGS.

The source line SL is set to Vs, for example, 0V.

As a result, the select gate transistor ST21 is turned on, and the voltage Vbl1 is transferred from the bit line BL1 to the channel of the selected cell MCk1 in the NAND string.

Therefore, when the program voltage Vpgm is applied to the word line WLk, electrons are injected into the charge storage layer (for example, floating gate electrode) from the channel in the selected cell MCk1, so that writing is carried out (threshold voltage rises).

On the other hand, when transfer voltages Vpash and Vpass-1, . . . , Vpass(k−2), Vpass-(k+1), . . . , Vpass-n are applied to the word line, for example, the channels in the memory cells in the NAND string are boosted due to capacity coupling. For this reason, the select gate transistor ST22 is automatically cut off.

When the program voltage Vpgm is applied to the word line WLk, the channel voltage of the selected cell MCk2 further rises. In the selected cell MCk2, therefore, electrons are not injected into the charge storage layer from the channel, so that the writing is inhibited (erase state is maintained).

In such a programming operation, transfer voltage Vpash higher than transfer voltages Vpass-1, Vpass-(k−2), Vpass-(k+1), . . . , Vpass-n is applied to the control gate electrode of the adjacent cells MC(k−1)1 and MC(k−1)2, namely, the word line WL(k−1).

For this reason, even if the programming is already finished in the adjacent cells (non-selected cells) MC(k−1)1 and MC(k−1)2 at the time of programming, a shift of the threshold voltages of the adjacent cells due to the leak between the control gate electrode of the selected cells and the charge storage layer of the adjacent cells can be prevented.

A case where the memory cells MCn1 and MCn2 which are the closest to the bit line side in the NAND string are the selected cells will be described below with reference to (b) of FIG. 7.

A program voltage Vpgm is applied to the word line WLn.

Transfer voltage Vpash is applied to the control gate electrode of the adjacent cells MC(n−1)1 and MC(n−1)2 adjacent to the source line SL sides of the selected cells MCn1 and MCn2, namely, the word line WL(n−1).

Transfer voltages Vpass-1, . . . , Vpass-(n−2) are applied to the other word lines WL1, . . . , WL(n−2).

When binary 0 is programmed in the selected cell MCn1 and binary 1 is programmed in the selected cell MCn2, the bit line BL1 is set to Vbl1, and the bit line BL2 is set to Vbl2 similarly to the above case.

The initial states of the selected cells MCn1 and MCn2 are in the erase state (1-state).

A voltage Vsgd is applied to the bit line side select gate line SGD. A voltage Vsgs for cutting off the source line side select gate transistors ST11 and ST12 is applied to the source line side select gate line SGS.

The source line SL is set to Vs, for example, 0V.

As a result, the select gate transistor ST21 is turned on, and the voltage Vbl1 is transferred from the bit line BL1 to the channel of the selected cell MCn1 in the NAND string.

Therefore, when the program voltage Vpgm is applied to the word line WLn, electrons are injected into the charge storage layer (for example, floating gate electrode) from the channel in the selected cell MCn1, so that writing is carried out (threshold voltage rises).

On the other hand, when transfer voltages Vpash and Vpass-1, . . . , Vpass-(n−2) are applied to the word lines, the channels of the memory cells in the NAND string are boosted due to the capacity coupling. For this reason, the select gate transistor ST22 is automatically cut off.

When the program voltage Vpgm is applied to the word line WLn, the channel voltage of the selected cell MCn2 further rises. In the selected cell MCn2, therefore, electrons are not injected into the charge storage layer from the channel, so that writing is inhibited (erase state is maintained).

In such a programming operation, transfer voltage Vpash higher than transfer voltages Vpass-1, Vpass-(n−2) is applied to the control gate electrode of the adjacent cells MC(n−1)1 and MC(n−1)2, namely, the word line WL(n−1).

For this reason, even if the programming is already finished in the adjacent cells (non-selected cells) MC(n−1)1 and MC(n−1)2 at the time of programming, the shift of the threshold voltages of the adjacent cells due to the leak between the control gate electrode of the selected cells and the charge storage layer of the adjacent cells can be prevented.

A case where the memory cells MC11 and MC12 which are the closest to the source line side in the NAND string are the selected cells will be described below with reference to (c) of FIG. 7.

In this case, since no adjacent cells adjacent to the source line SL sides of the selected cells MC11 and MC12 are present, the program voltage Vpgm is applied to the word line WL1, and transfer voltages Vpass-2, . . . , Vpass-n are applied to all the other word lines WL2, . . . , WLn.

Programming is carried out similarly to FIG. 7.

Also in the third example, since the relationship between ΔV and Vpash holds as shown in FIG. 9, the shift of the threshold voltages can be effectively prevented when the adjacent cells are in the writing state.

### D. Fourth Example

In a fourth example, transfer voltage Vpash is applied to at least one of the adjacent cell adjacent to the source line side of the selected cells and the adjacent cell adjacent to the bit line side.

The fourth example is effective for both the random program and the sequential program.

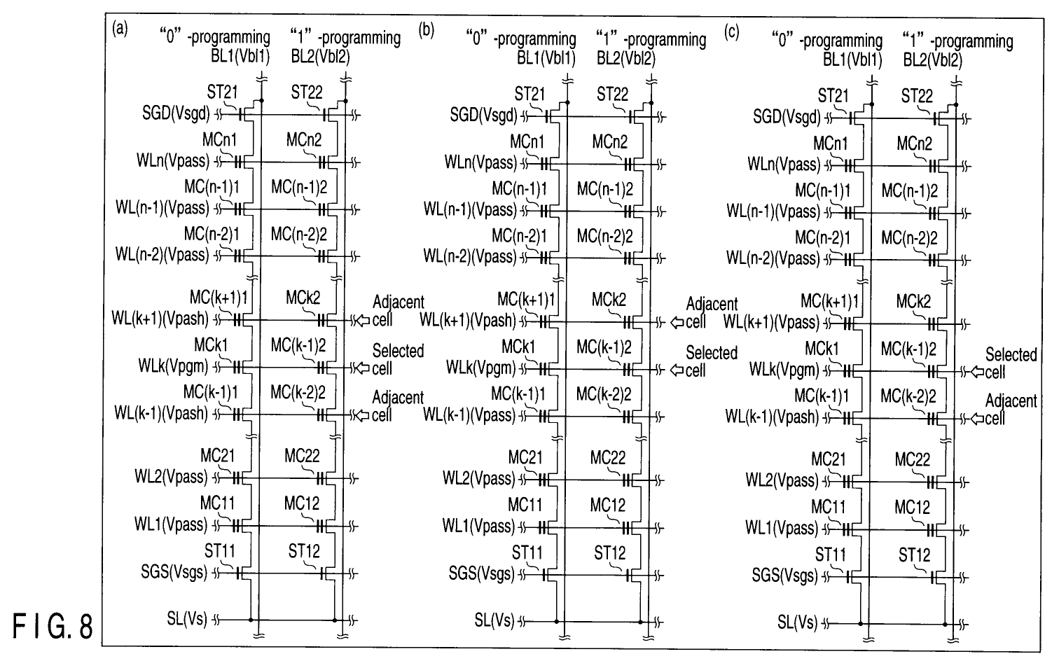

FIG. 8 illustrates a voltage relationship in the NAND cell unit at the time of programming.

In (a) of FIG. 8, a transfer voltage Vpash is applied to the control gate electrodes of the adjacent cells MC(k−1)1, MC(k−1)2, MC(k+1)1 and MC(k+1)2 adjacent to the source line SL sides and the bit lines BL1 and BL2 sides of the selected cells MCk1 and MCk2, namely, the word lines WL(k−1) and WL(k+1).

A program voltage Vpgm is applied to the word line WLk.

A transfer voltage Vpass is applied to the other word lines WL1, . . . , WL(k−2), WL(k+2), . . . , WLn.

A relationship among these three voltages is Vpass<Vpash<Vpgm.

Vpass, Vpash and Vpgm have values not less than a value for turning on the memory cells in the NAND string regardless of their threshold voltages.

It is considered that binary 0 is programmed in the selected cell MCk1 and binary 1 is programmed in the selected cell MCk2.

The initial states of the selected cells MCk1 and MCk2 are the erase state (1-state).

In this case, the bit line BL1 is set at a low voltage Vbl1 for the 0-programming, and the bit line BL2 is set at a positive voltage Vbl2 for the 1-programming.

A voltage Vsgd is applied to the bit line side select gate line SGD.

A voltage Vsgs for cutting off the source line side select gate transistors ST11 and ST12 is applied to the source line side select gate line SGS.

The source line SL is set to Vs, for example, 0V.

In this case, since transfer voltage Vpash higher than transfer voltage Vpass is applied to the two word lines WL(k−1) and WL(k+1), even if the programming is already finished in the adjacent cells (non-selected cells) MC(k−1)1, MC(k−1)2, MC(k+1)1 and MC(k+1)2 adjacent to the selected cell MCk, the shift of their threshold voltages can be prevented.

In (b) of FIG. 8, transfer voltage Vpash is applied to the control gate electrode of the adjacent cells MC(k+1)1 and MC(k+1)2 adjacent to the bit lines BL1 and BL2 sides of the selected cells MCk1 and MCk2, namely, the word line WL(k+1).

The program voltage Vpgm is applied to the word line WLk.

Transfer voltage Vpass is applied to the other word lines WL1, . . . , WL(k−1), WL(k+2), . . . , WLn.

The relationship among these three voltages is Vpass<Vpash<Vpgm.

Vpass, Vpash and Vpgm have values not less than a value for turning on the memory cells in the NAND string regardless of their threshold voltages.

It is considered that binary 0 is programmed in the selected cell MCk1 and binary 1 is programmed in the selected cell MCk2.

The initial states of the selected cells MCk1 and MCk2 are the erase state (1-state).

In this case, the bit line BL1 is set at a low voltage Vbl1 for the 0-programming, and the bit line BL2 is set at a positive voltage Vbl2 for the 1-programming.

A voltage Vsgd is applied to the bit line side select gate line SGD.

A voltage Vsgs for cutting off the source line side select gate transistors ST11 and ST12 is applied to the source line side select gate line SGS.

The source line SL is set to Vs, for example, 0V.

In this case, since transfer voltage Vpash higher than transfer voltage Vpass is applied to the word line WL(k+1), even if the programming is already finished in the adjacent cells (non-selected cells) MC(k+1)1 and MC(k+1)2 adjacent to the bit line side of the selected cell MCk, the shift of their threshold voltages can be prevented.

The (c) of FIG. 8 illustrates a case where transfer voltage Vpash is applied to the control gate electrode of the adjacent cells MC(k−1)1 and MC(k−1)2 adjacent to the source line SL sides of the selected cells MCk1 and MCk2, namely, the word line WL(k−1), and this is the same as the first example.

At least one of the local self-boost system in the second example and the varied transfer voltages Vpass-1, . . . , Vpass-n in the third example is applied to the fourth example, so that a new example can be provided.

### (5) Comparative Example

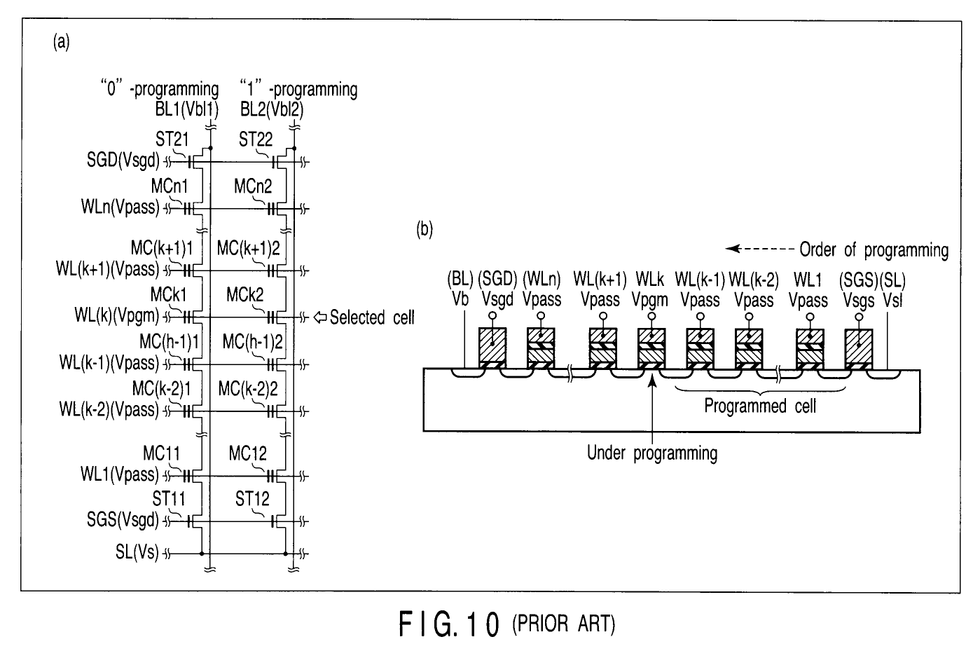

FIGS. 10 and 11 illustrate the programming operations as a comparative example.

The comparative example including the difference between the self-boost system, the local self-boost system and the system of the present invention will be described here.

Before programming, data in all the memory cells in the NAND cell unit are collectively erased. For example, all the word lines WL1, . . . , WLn are set at a low voltage Vss (for example, 0V), and a high positive voltage Vera (for example, 20V) is given to a semiconductor substrate (for example, p-type well region), so that electrons in the floating gate electrode are discharged into the channel.

The programming is collectively carried out in the memory cells connected to the selected word lines. Normally, a group of the memory cells connected to one word line is defined as one page, but in recent years pages are occasionally allocated to the memory cells.

Self-Boost System (FIG. 10)

Before the program voltage Vpgm is applied to the word lines, a voltage Vbl1/Vbl2 is applied to the bit lines BL1 and BL2 according to program data binary 0/1. The voltage Vbl1 is 0V, and the voltage Vbl2 has a value within a range of 1.2 to 4.0V.

A voltage Vsgs (for example, 0V) is given to the select gate line SGS of the source side select gate transistors ST11 and ST12, and a voltage Vsgd is given to the select gate line SGD of the bit line select gate transistors ST21 and ST22.

Thereafter, a program voltage Vpgm (for example, 20V) is given to the word line WLk connected to the selected cells MCk1 and MCk2, and a transfer voltage Vpass (for example, 10V) is given to the other word lines WL1, . . . , WL(k−1), . . . , WL(k+1), . . . , WLn.

Since the channel voltage in the NAND cell unit for the 0-programming is fixed to the voltage Vbl1, a large electric field is applied to a gate insulating film of the selected cell MCk1. Electrons are injected into its floating gate electrode, and thus the threshold voltage of the selected cell MCk1 rises.

On the other hand, in the NAND cell unit of the 1-programming, as shown in (b) of FIG. 10, the channels of all the memory cells in the NAND cell unit are connected to each other in series, and are electrically separated from the source line SL and the bit lines BL1 and BL2 so as to be in a floating state.

As a result, the channel voltage in the NAND cell unit of the 1-programming is boosted by the capacity coupling. For this reason, the electric field applied to the gate insulating film of the selected cell MCk2 is reduced, and thus the injection of the electrons into the floating gate electrode is suppressed.

In this system, since only one kind of transfer voltage Vpass is present, it is difficult to prevent the shift of the threshold voltages of the non-selected cells in which the programming is already finished.

For example, when the memory cells are miniaturized, as to the adjacent cells (non-selected cells) MC(k−1)1 and MC(k−1)2 adjacent to the selected cells MCk1 and MCk2, not only the shift of the threshold voltages due to a tunnel current flowing in the gate insulating film (tunnel insulating film) but also a leak current produced between the gate insulating film and the control gate electrode of the selected cell should be taken into consideration.

In this case, when the value of transfer voltage Vpass is too large, the tunnel current increases. To the contrary, when the value of transfer voltage Vpass is too small, the leak current increases. For this reason, it is very difficult to set transfer voltage Vpass to an optimum value.

Local Self-Boost System (FIG. 11)

This system is different from the self-boost system in that a cut off voltage Vcutoff (for example, 0V) for cutting off the adjacent cells MC(k−1)1 and MC(k−1)2 is given to the control gate electrode of the adjacent cells MC(k−1)1 and MC(k−1)2 adjacent to the source line SL side of the selected cells MCk1 and MCk2, namely, the word line WL(k−1). The other parts are the same as those of the self-boost system.

In this system, only the channel (boost area) of the memory cell which is closer to the bit lines BL1 and BL2 side than the adjacent cells (cut off transistors) MC(k−1)1 and MC(k−1)2 may be partially boosted. For this reason, the boost efficiency is improved.

In the local self-boost system, a transfer voltage Vpass is applied to the control gate electrode of the adjacent cells MC(k+1)1 and MC(k+1)2 adjacent to the bit lines BL1 and BL2 sides of the selected cells MCk1 and MCk2, namely, the word line WL(k+1).

Transfer voltage Vpass is lower than the program voltage Vpgm, and the cut off voltage Vcutoff to be given to the adjacent cells MC(k−1)1 and MC(k−1)2 adjacent to the source line SL sides of the selected cells MCk1 and MCk2 is lower than transfer voltage Vpass.

The cut off voltage Vcutoff, however, has a value for cutting off the adjacent cells MC(k−1)1 and MC(k−1)2 as its name suggests.

Transfer voltage Vpash in the system of the present invention has a value not less than the value for turning on the adjacent cells (non-selected cells) regardless of their threshold voltage. For this reason, the system of the present invention is completely discriminated from the local self-boost system.

### (6) Conclusion

According to the first to fifth examples, the shift of the threshold voltages of the non-selected cells in the NAND cell unit where data is already programmed can be prevented at the time of programming.

### 3. OPTIMIZATION OF THE TRANSFER VOLTAGE

In the present invention, at least two transfer voltages Vpass and Vpash are used so that the transfer voltage can be optimized easily.

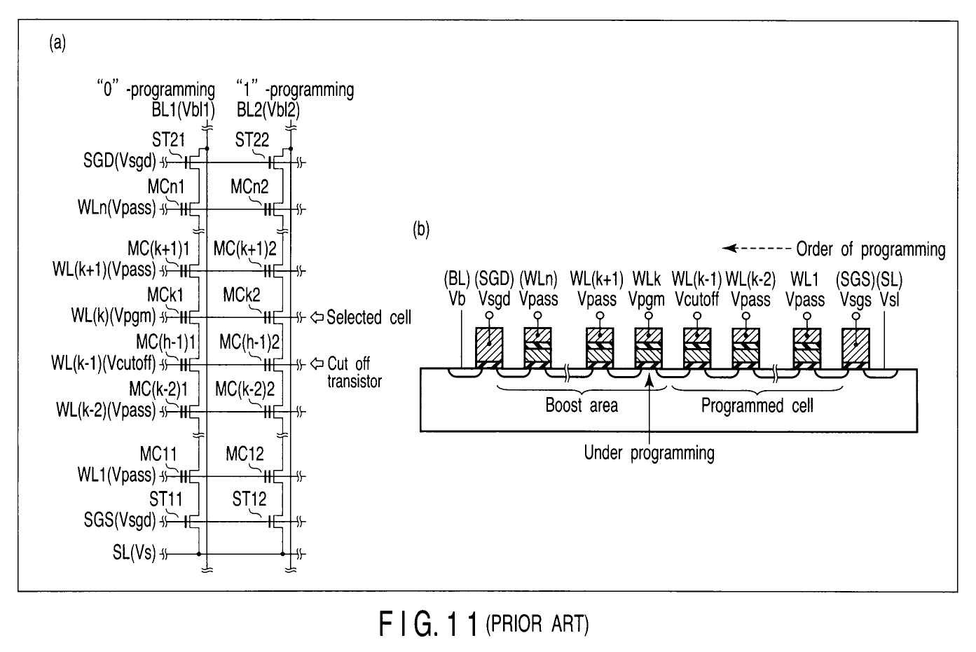

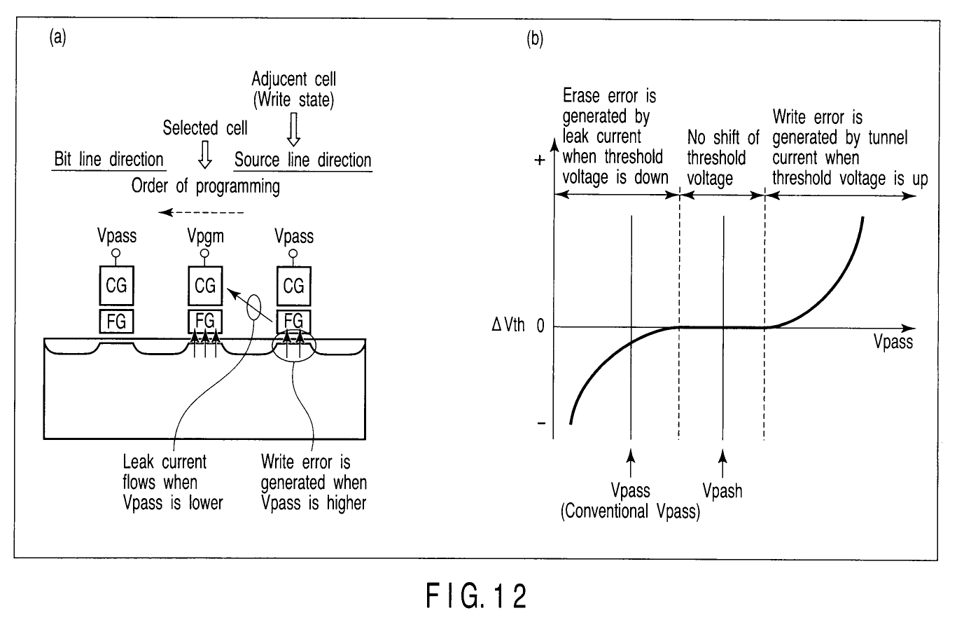

FIG. 12 illustrates a relationship between erase error due to the leak current and write error due to the tunnel current at the time of programming.

A problem of the write error due to the tunnel current arises in all the memory cells in the NAND cell unit, but the erase error due to the leak current, which is the problem of the present invention, arises only in the adjacent cells adjacent to the selected cells.

When only one kind of transfer voltage Vpass is present, only the write error due to the tunnel current is taken into consideration in conventional techniques. For this reason, transfer voltage Vpass is set to a comparatively low value. In this case, when the memory cells are miniaturized, the problem of the erase error of the adjacent cells due to the leak current arises.

Even when only one kind of transfer voltage Vpass is present, its value can be set within an optimum range. However, when a margin is taken into consideration, it is not preferable for the write error due to the tunnel current to collectively increase transfer voltage Vpass.

Like the present invention, therefore, in order to prevent write error due to the tunnel current, the value of transfer voltage Vpass which is the same as the conventional one is adopted. Further, in order to solve the problem of the erase error of the adjacent cells due to the leak current, transfer voltage Vpash higher than transfer voltage Vpass is given to the adjacent cells, which is very effective.

### 4. MODIFIED EXAMPLES

Some modified examples of the present invention will be described.

(1) Multi-Value NAND Type Nonvolatile Semiconductor Memory

The present invention is not limited to the number of values to be stored in one memory cell.

In the above examples, binary is premised, but the NAND type nonvolatile semiconductor memory of the present invention may be a multi-value memory which stores three or more values in one memory cell.

As already described, in the NAND type nonvolatile semiconductor memory to which the multi-value technique is applied, three or more threshold voltage distributions should be set within a narrow voltage range, and the prevention of the shift of threshold voltages according to the present invention is very effective for realizing the narrow threshold voltage distributions.

(2) Order of Programming

In the above examples, the order of programming is not particularly limited, but in the sequential program system, programming is successively executed from the memory cell which is closest to the source line side towards the memory cell which is closest to the bit line side in the memory cells in the NAND cell unit one by one. In this sequential program system, since the programming is finished in the adjacent cells adjacent to the source line side of the selected cells, the present invention is effective for preventing the shift of the threshold voltages of the adjacent cells.

Also in the random program system, the programming is occasionally finished in the adjacent cells adjacent to the selected cells. For this reason, the present invention is effective also for the NAND type nonvolatile semiconductor memory to which the random program system is applied.

(3) Sense System

A sense system which reads data from the memory cells includes a shield bit line sense system which reads data from even-numbered bit lines and odd-numbered bit lines separately and an all-bit-line (ABL) sense system which simultaneously reads data of all the bit lines.

The programming system of the present invention is combined with each of these shield bit line sense system and the ABL sense system, so that the NAND type nonvolatile semiconductor memory can be realized.

(4) Page Setting

The programming system of the present invention refers to the transfer voltage to be supplied to the adjacent cells when programming is collectively executed on the memory cells connected to one word line. A group which is composed of the memory cells to be connected to one word line is normally defined as one page.

In recent years, however, pages are occasionally allocated to the group which is composed of the memory cells to be connected to one word line. The programming system of the present invention can be applied to such a case without change.

(5) Channel Boost System

In the present invention, when the threshold voltages of selected cells are changed, the channels of the selected cells are fixed to a fixed electric potential (for example, 0V). When the threshold voltages of the selected cells are not changed, the channels of the selected cells are boosted to an electric potential higher than the fixed electric potential.

As such a system, the self-boost system, the local self-boost system, the erase area self-boost system (EBS) and their modified systems are known. The present invention can be, however, applied to such systems as a matter of course.

(6) Step-Up Writing

When writing which increases the threshold voltages of the selected cells is executed at the time of programming, the program voltage may be set so as to have a maximum value through steps. That is, a programming is executed by using a program voltage Vpgm+α higher than a program voltage Vpgm, when a threshold voltage of the selected memory cell does not become a predetermined value by a programming using the program voltage Vpgm. In this case, the value of the transfer voltage to be supplied to the adjacent cells may be lower than the maximum value of the program voltage.

The program voltage may have the same value as the value of the transfer voltage for a certain period before reaching the maximum value.

(7) Memory Cell Structure

In the above examples, it is assumed that the memory cells have a stack gate structure having floating gate electrodes and control gate electrodes. However, the memory cell structure is not limited to this.

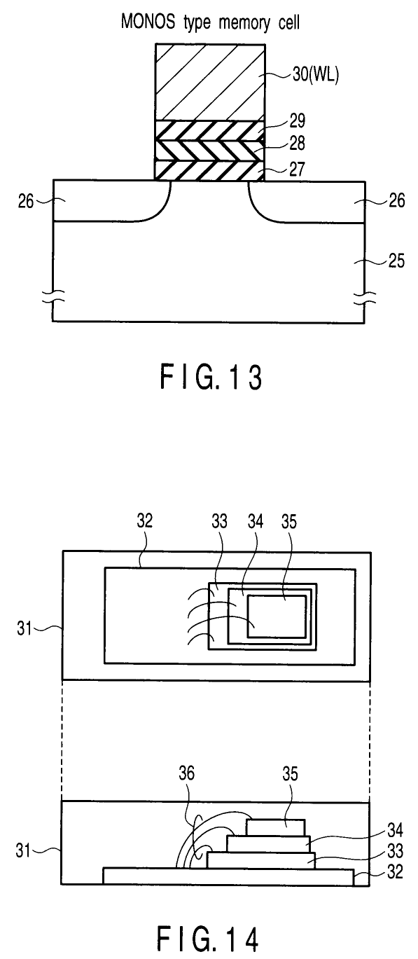

FIG. 13 illustrates an MONOS memory cell.

The MONOS memory cell is a nonvolatile semiconductor memory cell composed of a charge storage layer and an insulating film.

A source/drain diffusion layer 26 is arranged in a semiconductor substrate (active area) 25. A gate insulating film (tunnel insulating film) 27, a charge storage layer 28, a block insulating film 29 and a control gate electrode (word line) 30 are arranged on the channel region between the source drain diffusion layers 26.

The block insulating film 29 is made of, for example, an ONO (oxide/nitride/oxide) film, a high-dielectric-constant (high-k) material or the like.

### 5. APPLIED EXAMPLE

An example of the system to which the NAND type nonvolatile semiconductor memory of the present invention is applied will be described.

FIG. 14 illustrates one example of the memory system.

This system is, for example, a memory card, a USB memory or the like.

A circuit substrate 32, semiconductor chips 33, 34 and 35 are arranged in a package 31. The circuit substrate 32 and the semiconductor chips 33, 34 and 35 are electrically connected by a bonding wire 36. One of the semiconductor chips 33, 34 and 35 is the NAND type nonvolatile semiconductor memory of the present invention.

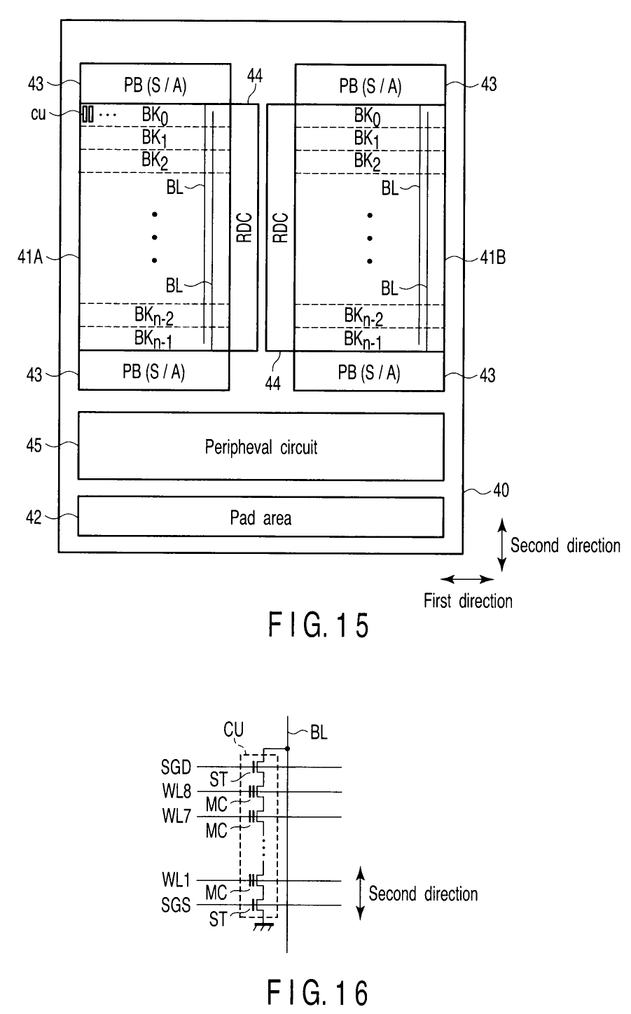

FIG. 15 illustrates a chip layout.

Memory cell arrays 41A and 41B are arranged on a semiconductor chip 40. Each of the memory cell arrays 41A and 41B has blocks BK0, BK1, . . . , BKn-1 arranged in the second direction. Each of the blocks BK0, BK1, . . . , BKn-1 has cell units CU which are arranged in the first direction.

As shown in FIG. 16, the cell unit CU is a NAND string which is composed of memory cells MC connected in series in the second direction and two select gate transistors ST connected to both ends of the memory cells MC, respectively.

The bit line BL which extends in the second direction is arranged on the memory cell arrays 41A and 41B. A page buffer (PB) 43 is arranged on both ends of the memory cell arrays 41A and 41B in the second direction. The page buffer 43 has a function for temporarily storing reading data/writing data at the time of reading/writing. The page buffer 43 functions as a sense amplifier at the time of reading operation or verification.

A row decoder (RDC) 44 is arranged at one ends (ends opposite to ends on edge sides of the semiconductor chip 40) of the memory cell arrays 41A and 41B in the first direction. A pad area 42 is arranged at one ends of the memory cell arrays 41A and 41B in the second direction along the edge of the semiconductor chip 40. A peripheral circuit 45 is arranged between the page buffer 43 and the pad area 42.

### 6. CONCLUSION

According to the present invention, the shift of threshold voltages of non-selected cells in the NAND cell unit where data is already programmed can be prevented.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A NAND type nonvolatile semiconductor memory comprising:
n-numbered memory cells (n is an integer of not less than 3) which have a charge storage layer and a control gate electrode and are connected to each other in series;
a first select gate transistor which is connected between one end of the n-numbered memory cells and a source line;
a second select gate transistor which is connected between the other end of the n-numbered memory cells and a bit line; and
a driver which applies a first voltage to a control gate electrode of a selected first memory cell in the n-numbered memory cells, applies a second voltage lower than the first voltage to a control gate electrode of a second memory cell adjacent to the first memory cell, and applies a third voltage lower than the second voltage to control gate electrodes of third memory cells other than the first and second memory cells at the time of programming,
wherein the first, second and third voltages have values not less than a value for turning on the n-numbered memory cells regardless of their threshold voltages.

2. The NAND type nonvolatile semiconductor memory according to claim 1,
wherein the second memory cell is adjacent to the source line side of the first memory cell.

3. The NAND type nonvolatile semiconductor memory according to claim 2,
wherein the programming is successively executed from the memory cell which is closest to the source line side toward the memory cell which is closest to the bit line side in the n-numbered memory cells one by one.

4. The NAND type nonvolatile semiconductor memory according to claim 1,
wherein different voltages are applied to control gate electrodes of (n−2)-numbered memory cells (n is an integer of not less than 4) other than the first and second memory cells at the time of the programming.

5. The NAND type nonvolatile semiconductor memory according to claim 1,
wherein a channel region of the first memory cell is fixed to a fixed electric potential, when a threshold voltage of the first memory cell is changed.

6. The NAND type nonvolatile semiconductor memory according to claim 1,
wherein an electric potential in a channel region of the first memory cell is boosted, when a threshold voltage of the first memory cell is not changed.

7. The NAND type nonvolatile semiconductor memory according to claim 1,
wherein the first voltage has a maximum value through steps, and the second and third voltages are lower than the maximum value at the time of the programming.

8. The NAND type nonvolatile semiconductor memory device according to claim 1,
wherein the first memory cell stores three or more-valued data.

9. A NAND type nonvolatile semiconductor memory comprising:
n-numbered memory cells (n is an integer of not less than 3) which have a charge storage layer and a control gate electrode and are connected to each other in series;
a first select gate transistor which is connected between one end of the n-numbered memory cells and a source line;
a second select gate transistor which is connected between the other end of the n-numbered memory cells and a bit line; and
a driver which applies a first voltage to a control gate electrode of a selected memory cell in the n-numbered memory cells, applies a second voltage lower than the first voltage to a control gate electrode of two adjacent memory cells adjacent to both sides of the selected memory cell, and applies a third voltage lower than the second voltage to control gate electrodes of non-selected memory cells other than the selected memory cell and the two adjacent memory cells at the time of programming,
wherein the first, second and third voltages have values not less than a value for turning on the n-numbered memory cells regardless of their threshold voltages.

10. The NAND type nonvolatile semiconductor memory according to claim 9,
wherein the programming is successively executed from the memory cell which is closest to the source line side toward the memory cell which is closest to the bit line side in the n-numbered memory cells one by one.

11. The NAND type nonvolatile semiconductor memory according to claim 9,
wherein different voltages are applied to control gate electrodes of (n−2)-numbered memory cells (n is an integer of not less than 4) other than the selected memory cell and the two adjacent memory cells at the time of the programming.

12. The NAND type nonvolatile semiconductor memory according to claim 9,
wherein a channel region of the selected memory cell is fixed to a fixed electric potential, when a threshold voltage of the selected memory cell is changed.

13. The NAND type nonvolatile semiconductor memory according to claim 9,
wherein an electric potential in a channel region of the selected memory cell is boosted, when a threshold voltage of the selected memory cell is not changed.

14. The NAND type nonvolatile semiconductor memory according to claim 9,
wherein the first voltage has a maximum value through steps, and the second and third voltages are lower than the maximum value at the time of the programming.

15. A NAND type nonvolatile semiconductor memory comprising:
n-numbered memory cells (n is an integer of not less than 3) which have a charge storage layer and a control gate electrode and are connected to each other in series;
a first select gate transistor which is connected between one end of the n-numbered memory cells and a source line;
a second select gate transistor which is connected between the other end of the n-numbered memory cells and a bit line; and
a driver which applies a first voltage to a control gate electrode of a selected first memory cell in the n-numbered memory cells, applies a second voltage lower than the first voltage to a control gate electrode of a second memory cell adjacent to the source line side of the first memory cell, applies a third voltage for cutting off a third memory cell adjacent to the source line side of the second memory cell to a control gate electrode of the third memory cell, and applies a fourth voltage lower than the second voltage to control gate electrodes of fourth memory cells other than the first, second and third memory cells at the time of programming,
wherein the first, second, and fourth voltages have values not less than a value for turning on the n-numbered memory cells regardless of their threshold voltages.

16. The NAND type nonvolatile semiconductor memory according to claim 15,
wherein the programming is successively executed from the memory cell which is closest to the source line side toward the memory cell which is closest to the bit line side in the n-numbered memory cells one by one.

17. The NAND type nonvolatile semiconductor memory according to claim 15,
wherein different voltages are applied to control gate electrodes of (n−2)-numbered memory cells (n is an integer of not less than 4) other than the first and second memory cells at the time of the programming.

18. The NAND type nonvolatile semiconductor memory according to claim 15,
wherein a channel region of the first memory cell is fixed to a fixed electric potential, when a threshold voltage of the first memory cell is changed.

19. The NAND type nonvolatile semiconductor memory according to claim 15,
wherein an electric potential in a channel region of the first memory cell is boosted, when a threshold voltage of the first memory cell is not changed.

20. The NAND type nonvolatile semiconductor memory according to claim 15,
wherein the first voltage has a maximum value through steps, and the second and third voltages are lower than the maximum value at the time of the programming.
